(19) United States
(12) Patent Application Publication
(10) Pub. No.: US 2007/0171618 A1
(43) Pub. Date: Jul. 26, 2007

(54) POWER SUPPLY MODULE AND LIGHTING TEST DEVICE FOR BACKLIGHT MODULE HAVING THE SAME

(75) Inventors: Kyu-Seok KIM, Yongin-si (KR); Young-Bee CHU, Suwon-si (KR); Dong-Cheol KIM, Suwon-si (KR); Byung-Woong HAN, Namdong-gu (KR); Young-Hee PARK, Busan (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/562,454

(22) Filed: Nov. 22, 2006

(30) Foreign Application Priority Data
Jan. 26, 2006 (KR) 10-2006-0008059

(51) Int. Cl. H05K 5/00

(52) U.S. Cl. 361/730

(57) ABSTRACT

A power supply module includes a pad and a fixing unit. The pad includes a plurality of anode power supply terminals and a plurality of cathode power supply terminals. The plurality of the anode power supply terminals and the cathode power supply terminals are alternately disposed. The fixing unit is capable of pressing an anode terminal and a cathode terminal of a printed circuit film from a backlight module to electrically connect the anode and cathode terminals to the anode power supply terminal and the cathode power supply terminal, respectively. Therefore, the backlight module having various types of anode and cathode terminals may be tested easily and efficiently.

This application claims priority to Korean Patent Application No. 10-2006-0008059, filed on Jan. 26, 2006, and all the benefits accruing there from under 35 U.S.C. § 119, the contents of which in its entirety are herein incorporated by reference.

### BACKGROUND OF THE INVENTION

1. Field of the Invention

The present invention relates to a power supply module and a lighting test device for a backlight module having the power supply module. More particularly, the present invention relates to a power supply module, which is capable of applying power to various types of backlight modules, and a lighting test device for a backlight module having the power supply module.

2. Description of the Related Art

In general, liquid crystal display (“LCD”) devices are used in personal computers, notebook computers, navigation systems for automobiles, television sets, etc., to display an image from data converted to electrical format. Since the LCD device has various merits, such as light weight, small volume, etc., the LCD device is widely used in various industrial fields.

The LCD device includes a backlight assembly providing light to a display panel in order to display an image in a dark environment. A small or medium-sized LCD device employed by a mobile device, such as a cellular phone or a personal digital assistant (“PDA”), includes a light-emitting diode (LED) to provide light to the display panel because the LED has low power consumption, small volume and light weight.

In order to reduce power consumption of the backlight assembly and to improve luminance uniformity of emitted light, lighting of the backlight assembly, luminance and luminance uniformity of the emitted light are tested during development and production stages. The LED includes a luminous body which is a kind of semiconductor. When the luminous body receives a driving current, the luminous body emits light. When an amount of the driving current provided to the luminous body is increased, the luminance of the light that the luminous body emits is increased. For the test, by varying an amount of the driving current provided to the LED, the lighting of the backlight assembly, the luminance of the emitted light and the luminance uniformity of light emitted from a plurality of the backlight assemblies are observed to improve uniformity and reliability of products.

More specifically, the backlight assembly includes a printed circuit film, an LED and a light-guiding plate. The printed circuit film receives the driving current from the external device. The LED is mounted on the printed circuit film and emits light according to the provided driving current. The light-guiding plate guides and emits light. In order to test the backlight assembly, an anode terminal and a cathode terminal of the printed circuit film are electrically connected to a power supply device. However, since a type or a shape of the anode and cathode terminals protruding from the printed circuit film varies according to a model of the backlight assembly, a power supply terminal of the power supply device may be electrically connected to the anode and cathode terminals by soldering or using alligator clips, depending on requirements at a given time. When the backlight assembly is tested by soldering or clipping the alligator clips to electrically connect the anode and cathode terminals with the respective power supply terminals, working efficiency is lowered and performing the tests corresponding to the various types of backlight assembly modules is difficult.

### BRIEF SUMMARY OF THE INVENTION

The present invention provides a power supply module capable of supplying power to various types of anode and cathode terminals drawn out from a backlight assembly.

The present invention also provides a lighting test device for a backlight module having the power supply module.

In an exemplary embodiment of a point light source according to the present invention, the power supply module includes a pad and a fixing unit. The pad includes a plurality of anode power supply terminals and a plurality of cathode power supply terminals. The anode power supply terminals and the cathode power supply terminals are alternately disposed. The fixing unit presses an anode terminal and a cathode terminal of a printed circuit film to connect the anode and cathode terminals to the anode power supply terminal and the cathode power supply terminal, respectively.

In exemplary embodiments, the anode power supply terminals and the cathode power supply terminals are alternately disposed along a first direction and a second direction perpendicular to the first direction. For example, a plurality of the anode power supply terminals and a plurality of the cathode power supply terminals may have a substantially flat shape and may be disposed in a matrix shape of 3×2.

In exemplary embodiments, a first separation distance between the cathode power supply terminal and the anode power supply terminal adjacent to the cathode power supply terminal is less than a second separation distance between the anode terminal and the cathode terminal. When a plurality of point light sources is mounted on the printed circuit film to be electrically connected with each other in parallel, the anode or the cathode terminals respectively supply a driving current to the point light sources. The anode or the cathode terminals are disposed in a connection area formed on the printed circuit film and the connection area has a first width, and the anode and the cathode power supply terminals have a second width being larger than the first width. The fixing unit includes a body, a cushion and a pressing bar. The body covers the pad. The cushion is disposed at an edge of the body and presses the anode terminal and the cathode terminal. The pressing bar is connected to the body and rotates the body to press the anode terminal and the cathode terminal into electrical contact with the anode power supply terminal and the cathode power supply terminal, respectively.

In an exemplary embodiment of a lighting test device for a backlight module according to the present invention, the lighting test device for a backlight module includes a substrate, a pad, a controller and a fixing unit. A plurality of test regions is defined on the substrate. The pad includes a plurality of anode power supply terminals and a plurality of cathode power supply terminals alternately disposed along a row direction and a column direction on a test region of the plurality of test regions. The controller controls a driving current supplied to the anode power supply terminals and the cathode power supply terminals. The fixing unit presses an anode terminal and a cathode terminal of a printed circuit film protruding from the backlight module to connect the anode and cathode terminals to the anode power supply terminal and the cathode power supply terminal, respectively.

In exemplary embodiments, the substrate includes a conductive pattern electrically connecting the controller to the anode and cathode power supply terminals. The substrate may further include a variable resistor, a current displaying part and an external power supply terminal. The variable resistor is electrically connected to the conductive pattern and controls the driving current supplied to the anode and cathode power supply terminals. The current displaying part displays an amount of the driving current. When lighting of the backlight module is tested precisely, the external power supply terminal receives the driving current from an external power supply unit.

According to the present invention, power may be easily supplied to the various types of anode and cathode terminals protruding from the printed circuit film, and thereby lighting of the backlight module may be efficiently tested.

### BRIEF DESCRIPTION OF THE DRAWINGS

The above and other aspects, features and advantages of the present invention will become readily apparent by reference to the following detailed description when considered in conjunction with the accompanying drawings wherein:

FIG. 1 is a perspective view illustrating an exemplary embodiment of a power supply module in accordance with the present invention;

FIG. 2 is a top plan view illustrating the power supply module in FIG. 1 for supplying a driving current to a first backlight module;

FIG. 3 is a cross-sectional view illustrating the power supply module taken along line of I-I′in FIG. 2;

FIG. 4 is a perspective view illustrating the power supply module in FIG. 1 for supplying a driving current to a second backlight module;

FIG. 5 is a perspective view illustrating the power supply module in FIG. 1 for supplying a driving current to a third backlight module;

FIG. 6 is a perspective view illustrating the power supply module in FIG. 1, for supplying a driving current to a fourth backlight module;

FIG. 7 is a perspective view illustrating the power supply module in FIG. 1 for supplying a driving current to a fifth backlight module;

FIG. 8 is a plan view illustrating an exemplary embodiment of a lighting test device for a backlight module in accordance with the present invention;

FIG. 9 is an enlarged view illustrating portion “A” in FIG. 8; and

FIG. 10 is an enlarged view illustrating portion “B” in FIG. 8.

### DETAILED DESCRIPTION OF THE INVENTION

It should be understood that the exemplary embodiments of the present invention described below may be varied or modified in many different ways without departing from the inventive principles disclosed herein, and the scope of the present invention is therefore not limited to these particular flowing exemplary embodiments. Rather, these exemplary embodiments are provided so that this disclosure will be thorough and complete, and will fully convey the concept of the invention to those skilled in the art by way of example and not of limitation.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items. Spatially relative terms, such as “beneath,” “below,” “lower,” “above,” “upper” and the like, may be used herein for ease of description to describe one element or feature's relationship to another element(s) or feature(s) as illustrated in the figures.

It will be understood that, although the terms first, second, third etc. may be used herein to describe various elements, members, components, regions, layers and/or sections, these elements, members, components, regions, layers and/or sections should not be limited by these terms. These terms are only used to distinguish one element, member, component, region, layer or section from another element, member, component, region, layer or section. Thus, a first element, component, member, region, layer or section discussed below could be termed a second element, component, member, region, layer or section without departing from the teachings of the present invention.

It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the present invention will be described in more detail with reference to the accompanied drawings.

<Power Supply Module>,

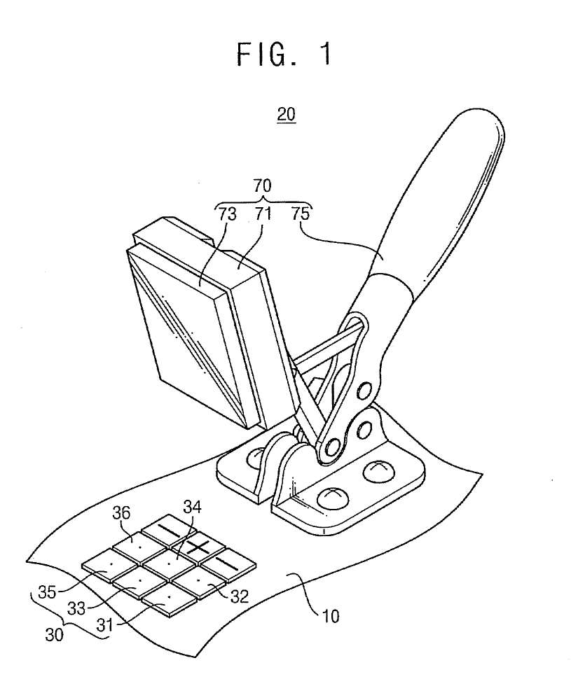

FIG. 1 is a perspective view illustrating an exemplary embodiment of a power supply module in accordance with the present invention.

Referring to FIG. 1, the power supply module 20 includes a pad 30 and a fixing unit 70. The power supply module 20 is disposed on a substrate 10. A conductive pattern that supplies a driving current to the pad 30 is formed on the substrate 10. The conductive pattern is covered by an insulating layer, except for a connecting portion. The power supply module 20 supplies power to an anode terminal and a cathode terminal of a backlight module (not shown). For example, the power supply module 20 supplies a driving current of a point light source to the anode and cathode terminals of a printed circuit film, on which the point light source is mounted.

The pad 30 includes a first anode power supply terminal 31, a second anode power supply terminal 35, a third anode power supply terminal 34, a first cathode power supply terminal 33, a second cathode power supply terminal 32 and a third cathode power supply terminal 36. The first, second and third anode power supply terminals 31, 35 and 34 and the first, second and third cathode power supply terminals 33, 32 and 36 are alternately disposed with each other.

In detail, the first, second and third anode power supply terminals 31, 35 and 34 and the first, second and third cathode power supply terminals 33, 32 and 36 may have a substantially flat rectangular shape. The first, second and third anode power supply terminals 31, 35 and 34 and the first, second and third cathode power supply terminals 33, 32 and 36 may be disposed alternately along a first direction and a second direction perpendicular to the first direction. Alternatively, the first, second and third anode power supply terminals 31, 35 and 34 and the first, second and third cathode power supply terminals 33, 32 and 36 may be alternately disposed on a curved line.

Therefore, along a first row, the first anode power supply terminal 31, the first cathode power supply terminal 33 and the second anode power supply terminal 35 may be disposed in that order. Also, along a second row, the second cathode power supply terminal 32, the third anode power supply terminal 34 and the third cathode power supply terminal 36 may be disposed in that order. Therefore, the first, second and third anode power supply terminals 31, 35 and 34 and the first, second and third cathode power supply terminals 33, 32 and 36 may be disposed in a matrix shape of 3×2.

Alternatively, the number of the anode and cathode power supply terminals of the power supply module 20 may be variously changed. For example, the first, second and third anode power supply terminals 31, 35 and 34 and the first, second and third cathode power supply terminals 33, 32 and 36 may be disposed in a matrix shape of 5×2, in a matrix shape of 3×3, etc.

The first, second and third anode power supply terminals 31, 35 and 34 and the first, second and third cathode power supply terminals 33, 32 and 36 may include copper having excellent electrical conductivity. The first, second and third anode power supply terminals 31, 35 and 34 and the first, second and third cathode power supply terminals 33, 32 and 36 are connected with the connecting portion of the conductive patterns. Anode power is respectively supplied to the first, second and third anode power supply terminals 31, 35 and 34 through the conductive patterns, and cathode power is respectively supplied to the first, second and third cathode power supply terminals 33, 32 and 36 through the conductive patterns.

According to a shape of a printed circuit film of a backlight assembly (not shown), the anode terminal may be disposed on one of the first, second and third anode power supply terminals 31, 35 and 34, and the cathode terminal may be disposed on one of the first, second and third cathode power supply terminals 33, 32 and 36.

For example, when the anode terminal is disposed at the first anode power supply terminal 31, the cathode terminal may be disposed at the first cathode power supply terminal 33 or the second power supply terminal 32 adjacent to the first anode power supply terminal 31. When the cathode terminal is disposed at the first cathode power supply terminal 33, the anode terminal may be disposed at the second anode power supply terminal 35.

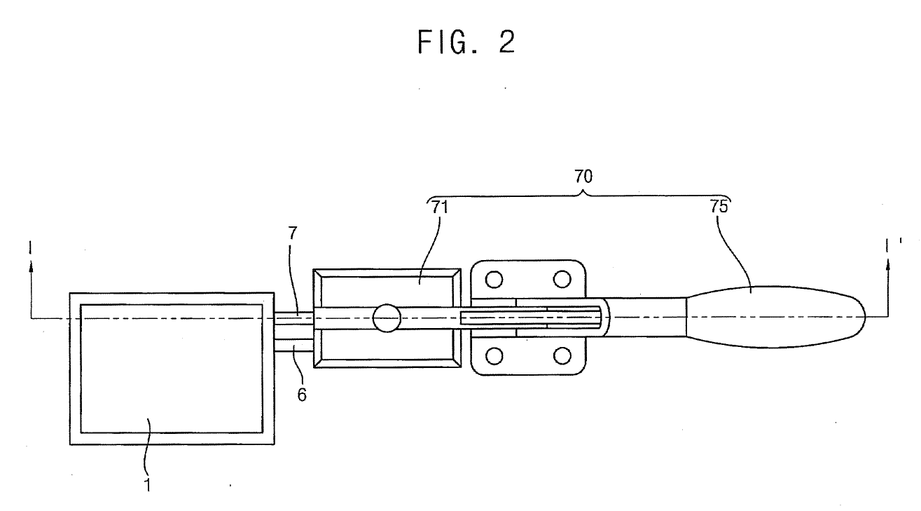

The first, second and third anode power supply terminals 31, 35 and 34 and the first, second and third cathode power supply terminals 33, 32 and 36 may be separated from each other by a first separation distance. The anode and cathode terminals of the first backlight module (see FIG. 2) are drawn out to be separated from each other by a second separation distance (see distance between anode terminal 6 and cathode terminal 7 in FIG. 2, for example). Therefore, in order that the anode and cathode terminals disposed at the first, second and third anode power supply terminals 31, 35 and 34 and the first, second and third cathode power supply terminals 33, 32 and 36 are disposed adjacent to each other, the first separation distance is desirably smaller than the second separation distance.

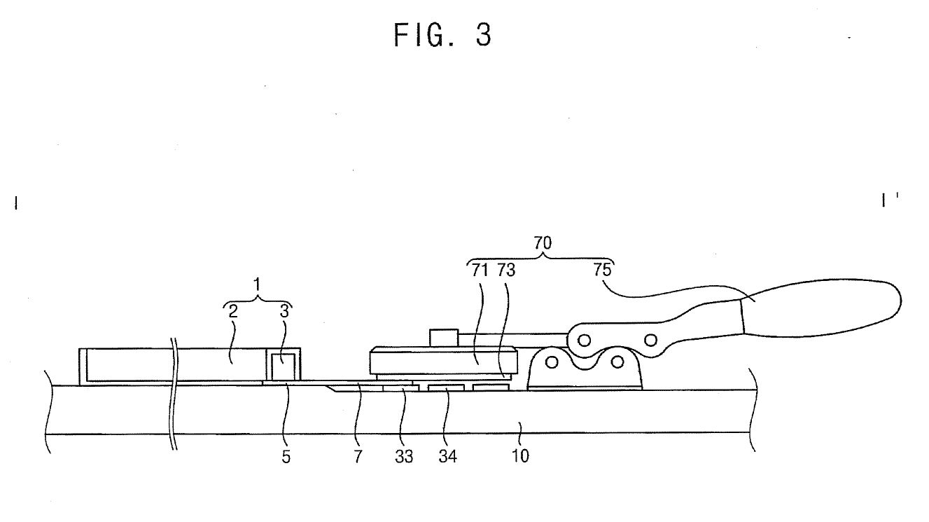

FIG. 2 is a top plan view illustrating the power supply module in FIG. 1 for supplying a driving current to a first backlight module. FIG. 3 is a cross-sectional view illustrating the power supply module taken along line of I-I′ in FIG. 2.

Referring to FIGS. 2 and 3, a first backlight module 1 includes a printed circuit film 5, a point light source 3 and a light-guiding plate 2. The printed circuit film 5 receives a driving current of the point light source 3 from a power supply (not shown). The printed circuit film 5 includes a flexible base film and a conductive line formed on the base film. The conductive line is drawn out or protrudes from an end portion of the printed circuit film 5 and forms an anode terminal 6 and a cathode terminal 7 receiving the driving current. The point light source 3 is mounted on the printed circuit film 5 and emits a light according to the driving current that is supplied thereto. The light-guiding plate 2 guides the light that enters the light-guiding plate 2 through a side surface thereof to emit the light.

On a basis of the line of I-I′ in FIG. 2, a position where the first backlight module 1 is disposed is defined as an upper portion and a position where the power supply module 20 is disposed is defined as a lower portion. Also, a left portion and a right portion are defined by a direction that is perpendicular to the line of I-I′. Then, the anode terminal 6 is drawn out along a straight direction from a lower end portion of the right portion of the first backlight module 1, and the cathode terminal 7 is drawn out along a straight direction from the lower end portion of the right portion of the first backlight module 1 to the right of the anode terminal 6.

Since the anode terminal 6 is disposed to the left of the cathode terminal 7, the anode and cathode terminals 6 and 7 are preferably disposed on substantially the same line. Therefore, as shown in FIGS. 2 and 3 with reference to FIG. 1, the anode terminal 6 is preferably disposed at the first anode power supply terminal 31, and the cathode terminal 7 is preferably disposed at the first cathode power supply terminal 33.

The fixing unit 70 presses the anode terminal 6 and the cathode terminal 7 and ensures an electrical connection between the first anode power supply terminal 31 and the first cathode power supply terminal 33. The fixing unit 70 includes a body 71, a cushion 73 and a pressing bar 75.

The body 71 includes a first surface that has a larger area than that of the pad 30, and a second surface facing the first surface. The cushion 73 is disposed on the surface of the body 71. The cushion 73 may desirably include an electrical-insulating resin that contacts the anode terminal 6 and the cathode terminal 7 closely.

The pressing bar 75 is fixed to the substrate 10 and the second surface of the body 71. Then, the pressing bar 75 is connected to the body 71 through a rotating arm to rotate with respect to the body 71. As the pressing bar 75 rotates along a clockwise direction toward the substrate 10, the body 71 rotates along an opposite direction to rotate the cushion 73 to cover the pad 30. Then, the cushion 73 presses the anode terminal 6 and the cathode terminal 7 into electrical contact with the anode power supply terminal and the cathode power supply terminal, respectively. Therefore, the anode terminal 6 makes close contact with the first anode power supply terminal 31, and the cathode terminal 7 makes close contact with the first cathode power supply terminal 33, respectively.

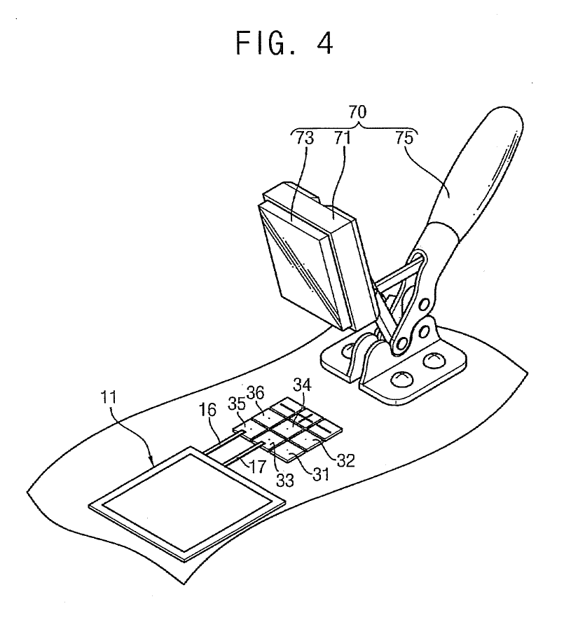

FIG. 4 is a perspective view illustrating the power supply module in FIG. 1 for supplying a driving current to a second backlight module.

Referring to FIG. 4, a second backlight module 11 is substantially the same as the first backlight module 1 in FIGS. 2 and 3, except for where an anode terminal 16 and a cathode terminal 17 are drawn out from the second backlight module 11.

As shown in FIG. 4, the anode terminal 16 is drawn out along a straight direction from a lower end portion of a right portion of the second backlight module 11, and the cathode terminal 17 is drawn out along a straight direction from the lower end portion of the right portion of the second backlight module 11 to the left of the anode terminal 16.

Therefore, since the anode terminal 16 is disposed to the right of the cathode terminal 17, the anode terminal 16 is desirably disposed at the second anode power supply terminal 35, and the cathode terminal 17 is desirably disposed at the first cathode power supply terminal 33.

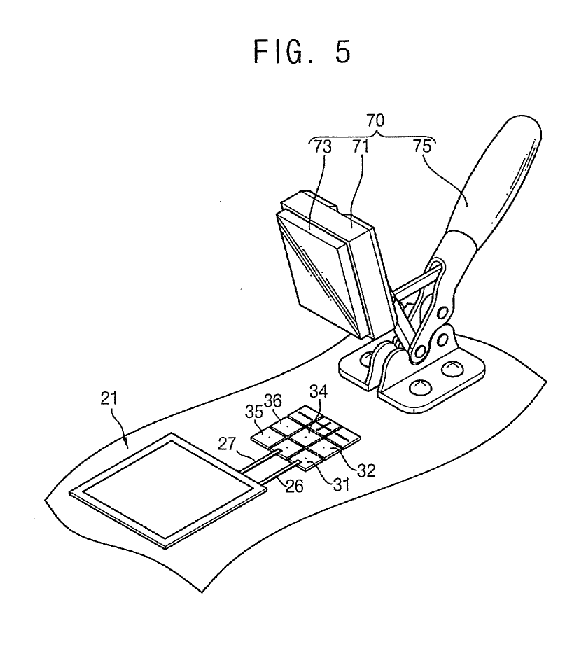

FIG. 5 is a perspective view illustrating the power supply module in FIG. 1 for supplying a driving current to a third backlight module.

Referring to FIG. 5, a third backlight module 21 is substantially the same as the first backlight module 1 in FIGS. 2 and 3, except for where an anode terminal 26 and a cathode terminal 27 protrude from the third backlight module 21.

As shown in FIG. 5, the anode terminal 26 is drawn out along a straight line direction from a lower end portion of a left portion of the third backlight module 21, and the cathode terminal 27 is drawn out along a straight line direction from the lower end portion of the left portion of the third backlight module 21 to a right portion of the anode terminal 26.

Therefore, since the anode terminal 26 is disposed to the left of the cathode terminal 27, the anode terminal 26 is desirably disposed at the first anode power supply terminal 31, and the cathode terminal 27 is desirably disposed at the first cathode power supply terminal 33.

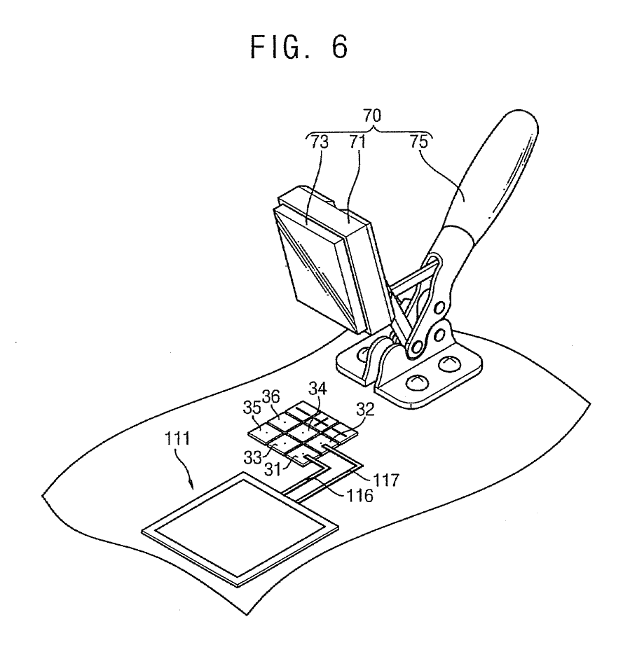

FIG. 6 is a perspective view illustrating the power supply module in FIG. 1 for supplying a driving current to a fourth backlight module.

Referring to FIG. 6, a fourth backlight module 111 is substantially the same as the first backlight module 1 in FIGS. 2 and 3, except for where an anode terminal 116 and a cathode terminal 117 are drawn out from the fourth backlight module 111.

As shown in FIG. 6, the anode terminal 116 is drawn out by a predetermined length from a middle portion of the fourth backlight module 111 to be perpendicular to a lower end portion of the fourth backlight module 111 and then is extends to the right. Thus, the anode terminal 116 may have an “L” shape. The cathode terminal 117 is drawn out by a longer length compared to the length of the anode terminal 116 from the left of the anode terminal 116 to be perpendicular to the lower end portion of the fourth backlight module 111 and then extends to the right. Thus, the cathode terminal 117 may have an “L” shape.

Therefore, since the anode and cathode terminals 116 and 117 have an “L” shape having the end portions folded to the right, the anode and cathode terminals 116 and 117 are preferably disposed on different lines. Therefore, the anode terminal 116 is desirably disposed at the first anode power supply terminal 31 and the cathode terminal 117 is desirably disposed at the second cathode power supply terminal 32.

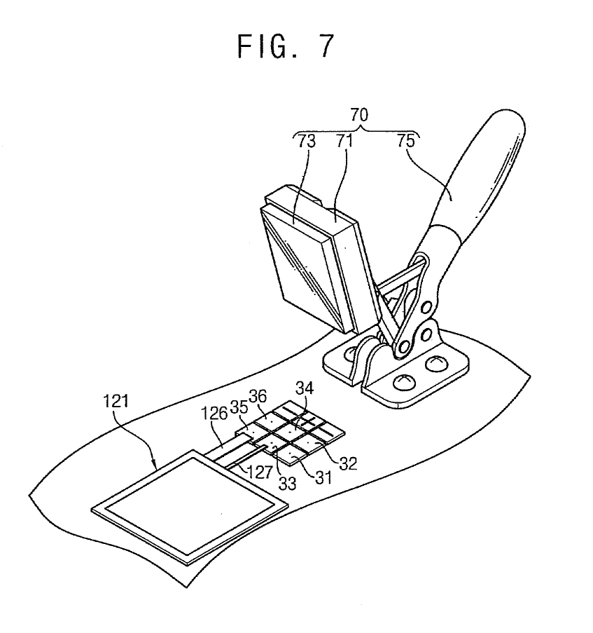

FIG. 7 is a perspective view illustrating the power supply module in FIG. 1 for supplying a driving current to a fifth backlight module.

Referring to FIG. 7, a fifth backlight module 121 is substantially the same as the first backlight module 1 in FIGS. 2 and 3, except for a mounting method of a point light source on a printed circuit film, and where an anode terminal 126 and a cathode terminal 127 are drawn out from the fifth backlight module 121. A plurality of the point light sources of the fifth backlight module 121 is mounted on the printed circuit film to be electrically connected to the printed circuit film in parallel.

Therefore, a plurality of the anode and cathode terminals 126 and 127 respectively supplying a driving current to the plurality of the point light sources are formed on the printed circuit film. The plurality of the anode and cathode terminals 126 and 127 may be connected with each other to form one line on the printed circuit film. Alternatively, a plurality of the anode and cathode terminals 126 and 127 may be separately drawn out to an edge of the printed circuit film.

A plurality of the anode terminals 126 of the fifth backlight module 121 is respectively drawn out to a connection area formed at the edge of the printed circuit film. Then, the connection area may have a first width along the row direction. A plurality of the cathode terminals 127 is drawn out to be connected with one line on the printed circuit film. Therefore, a first branch of the printed circuit film, from which a plurality of the anode terminals 126 is drawn out, as shown in FIG. 7, may have a wider width than a second branch of the printed circuit film, from which a plurality of the cathode terminals 127 is drawn out to be connected with one line.

A plurality of the anode terminals 126 is disposed at one of the first, second and third anode power supply terminals 31, 35 and 34. Thus, in order that the driving current is supplied simultaneously to the plurality of the anode terminals 126, the first, second and third anode power supply terminals 31, 35 and 34 may desirably have a second width that is wider than the first width of the connection area. Also, the first, second and third cathode power supply terminals 33, 32 and 36 may be desirably formed to correspondingly have a third width to the fifth backlight module 121, so that a plurality of the cathode terminals 127 is respectively drawn out. The third width may be substantially same as the second width.

As shown in FIG. 7, the anode terminal 126 is drawn out along a straight direction from a lower end portion of a right portion of the fifth backlight module 121, and the cathode terminal 127 is drawn out along a straight direction from the lower end portion of the right portion of the fifth backlight module 121 and to the left of the anode terminal 126.

Therefore, since the anode terminal 126 is disposed to the right of the cathode terminal 127, the anode terminal 126 is desirably disposed at the second anode power supply terminal 35 and the cathode terminal 127 is desirably disposed at the first cathode power supply terminal 33.

<Lighting Test Device for a Backlight Module>

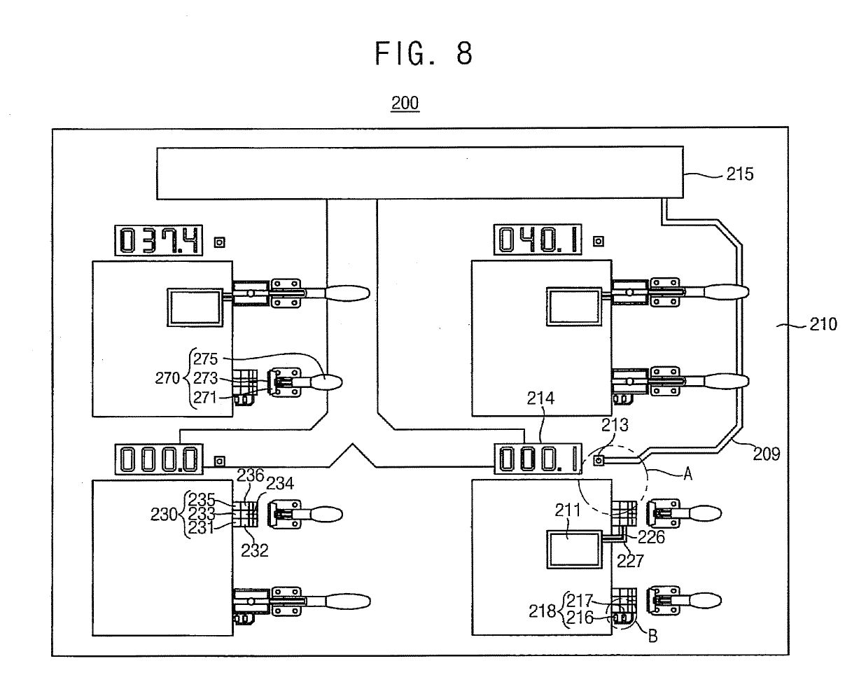

FIG. 8 is a plan view illustrating an exemplary embodiment of a lighting test device for a backlight module in accordance with the present invention.

Referring to FIG. 8, the lighting test device for the backlight module 200 may be used to test for lighting of a backlight module 211, comparing luminance between the backlight modules 211, and an amount of driving current and luminance of emitted light. For example, the backlight module 211 may be substantially the same as at least one of the first, second, third, fourth and fifth backlight modules 1, 11, 21, 111 and 121 in FIGS. 1 to 7.

In detail, the first, second, third, fourth and fifth backlight modules 1, 11, 21, 111 and 121 in FIGS. 1 to 7 may be applied to a small or medium-sized LCD device, such as a cellular phone or a plasma display panel (“PDP”) display device. Also, the lighting test device for the backlight module 200 may be used to test display quality of a display device having a display panel and the backlight module 211 combined with each other.

The lighting test device for the backlight module 200, supplies a driving current of the point light source to an anode terminal 216 and a cathode terminal 217 of a printed circuit film drawn out from the backlight module 211 as shown in FIGS. 2 and 3, respectively. The lighting test device for the backlight module 200 includes a substrate 210, a pad 230, a controller 215 and a fixing unit 270.

The substrate 210 includes insulating layers and a conductive pattern that is formed between the insulating layers. The lighting test device for the backlight module 200 may simultaneously test a plurality of the backlight modules 211 having various types of anode and cathode terminals 216 and 217. For this, a plurality of test regions is defined on the substrate 210 (e.g., four test regions each with two fixing units 270 illustrated in FIG. 8).

The pad 230 is formed in each of the test regions and may be substantially the same as the pad 30 in FIG. 1. Therefore, the pad 230 includes a first anode power supply terminal 231, a second anode power supply terminal 235, a third anode power supply terminal 234, a first cathode power supply terminal 233, a second cathode power supply terminal 232 and a third cathode power supply terminal 236.

The first, second and third anode power supply terminals 231, 235 and 234 and the first, second and third cathode power supply terminals 233, 232 and 236 are disposed alternately along a row direction and a column direction. The first, second and third anode power supply terminals 231, 235 and 234 and the first, second and third cathode power supply terminals 233, 232 and 236 are separated from each other by the first separation distance and are formed to have the second width, respectively.

The first, second and third anode power supply terminals 231, 235 and 234 receive a positive voltage through the conductive pattern 209, and the first, second and third cathode power supply terminals 233, 232 and 236 receive a negative voltage through the conductive pattern 209.

The controller 215 is disposed at an edge of the substrate 210. The controller 215 is electrically connected to the first, second and third anode power supply terminals 231, 235 and 234 and the first, second and third cathode power supply terminals 233, 232 and 236 through the conductive pattern 209. The controller 215 controls the driving current to meet characteristics of the backlight module 211.

The fixing unit 270 may be substantially the same as the fixing unit 70 in FIGS. 1 to 3. Therefore, the fixing unit 270 includes a body 271, a cushion 273 and a pressing bar 275. The cushion 273 is disposed on a first surface of the body 271. The pressing bar 275 is connected to a second surface of the body 271 corresponding to the first surface.

The pressing bar 275 is fixed to the substrate 210. As the pressing bar 275 is pressed toward the substrate 210, the body 271 rotates in an opposite direction to the pressing bar 275 to cover the pad 230 to press the anode and cathode terminals 216 and 217 into electrical contact with the anode power supply terminals 231, 235 and 234 and the cathode power supply terminals 233, 232 and 236, respectively. Therefore, the anode and cathode terminals 216 and 217 respectively make contact with one of the first, second and third anode power supply terminals 231, 235 and 234 and one of the first, second and third cathode power supply terminals 233, 232 and 236.

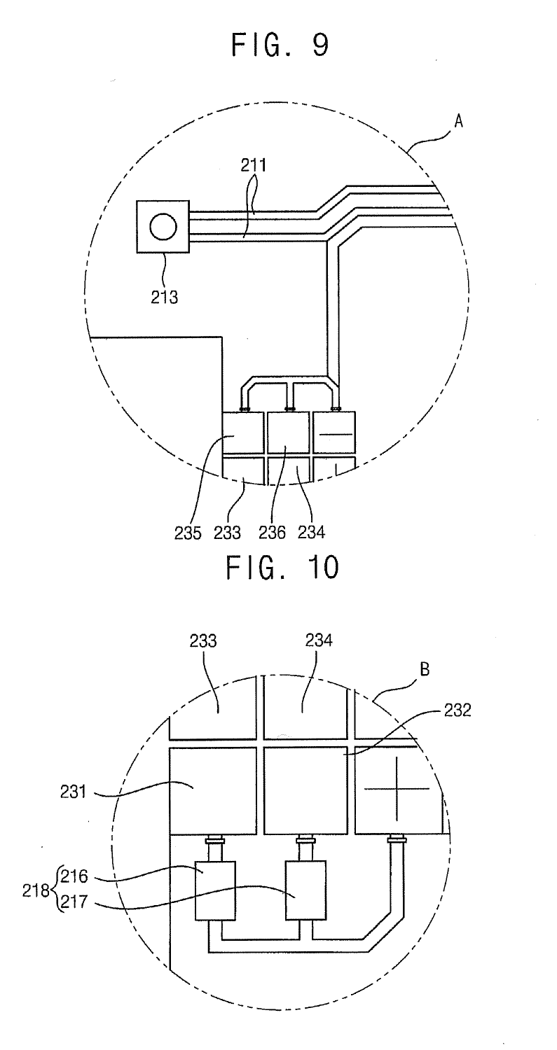

FIG. 9 is an enlarged view illustrating portion “A” in FIG. 8.

Referring to FIGS. 8 and 9, the lighting test device for the backlight module 200 may further include a variable resistor 213 and a current displaying part 214.

The variable resistor 213 is electrically connected to the conductive pattern 209. The driving current is controlled by the variable resistor 213. As the driving current supplied to the backlight module 211 is changed, a variation of luminance of light emitted from the backlight module 211 and the amount of the driving current for reducing power consumption may be tested. The current displaying part 214 displays an amount of the driving current supplied to the pad 230 as digital data.

FIG. 10 is an enlarged view illustrating portion “B” in FIG. 8.

Referring to FIG. 10, the lighting test device for the backlight module 200 may further include an external power supply terminal 218. The external power supply terminal 218 includes an anode external power supply terminal 216 and a cathode external power supply terminal 217.

For testing of the backlight module 211, when the driving current is desired to be controlled more precisely in comparison with control by the variable resistor 213, the driving current is controlled more precisely by an external power supply unit (not shown) supplied to the external power supply terminal 218.

According to the present invention, a power supply module and a lighting test device for a backlight module having the power supply module include a pad, which is capable of supplying power corresponding to various types of terminals of the backlight module. Therefore, lighting of the backlight module and variation of luminance of the emitted light corresponding to the driving current may be tested easily and efficiently.

The present invention has been described with reference to the exemplary embodiments. It is evident, however, that many alternative modifications and variations will be apparent to those having skill in the art in light of the foregoing description. Accordingly, the present invention embraces all such alternative modifications and variations as falling within the spirit and scope of the appended claims.

What is claimed is:

1. A power supply module comprising:
a pad including a plurality of anode power supply terminals and cathode power supply terminals which are alternately disposed; and
a fixing unit which presses an anode terminal and a cathode terminal of a printed circuit film to electrically connect the anode and cathode terminals to the anode power supply terminal and the cathode power supply terminal, respectively.

2. The power supply module of claim 1, wherein the anode power supply terminals and the cathode power supply terminals are alternately disposed along a first direction and a second direction perpendicular to the first direction.

3. The power supply module of claim 2, wherein the anode power supply terminals and the cathode power supply terminals have a substantially flat shape and are disposed in a matrix shape of 3×2.

4. The power supply module of claim 2, wherein a first separation distance between a cathode power supply terminal and an anode power supply terminal adjacent to the cathode power supply terminal is less than a second separation distance between the anode terminal and the cathode terminal.

5. The power supply module of claim 2, wherein a plurality of point light sources is mounted on the printed circuit film to be electrically connected with each other in parallel,
a plurality of the anode or the cathode terminals respectively supplying a driving current to the point light sources are disposed in a connection area formed on the printed circuit film, the connection area having a first width, and
the anode and the cathode power supply terminals each have a second width larger than the first width.

6. The power supply module of claim 1, wherein the fixing unit comprises:
a body covering the pad;
a cushion being disposed at an edge of the body and pressing the anode terminal and the cathode terminal; and
a pressing bar being connected to the body and rotating the body to press the anode terminal and the cathode terminal into electrical contact with the anode power supply terminal and the cathode power supply terminal, respectively.

7. A lighting test device for a backlight module, comprising:
a substrate having a plurality of test regions defined thereon;
a pad including a plurality of anode power supply terminals and cathode power supply terminals alternately disposed along a row direction and a column direction at a test region of the plurality of test regions;
a controller controlling a driving current supplied to the anode power supply terminals and the cathode power supply terminals; and
a fixing unit pressing an anode terminal and a cathode terminal of a printed circuit film, which protrude from the backlight module, to connect the anode and cathode terminals to the anode power supply terminal and the cathode power supply terminal, respectively.

8. The lighting test device for a backlight module of claim 7, wherein the substrate includes a conductive pattern electrically connecting the controller to the anode and cathode power supply terminals.

9. The lighting test device for a backlight module of claim 8, wherein the substrate further includes a variable resistor electrically connected to the conductive pattern to control the driving current supplied to the anode and cathode power supply terminals.

10. The lighting test device for a backlight module of claim 8, wherein the substrate further includes a current displaying part which displays an amount of the driving current supplied to the anode and cathode power supply terminals.

11. The lighting test device for a backlight module of claim 8, wherein the substrate further includes an external power supply terminal receiving the driving current from an external power supply unit when lighting of the backlight module is tested precisely.
